(19) United States
(12) Patent Application Publication
(10) Pub. No.: US 2007/0251088 A1
(43) Pub. Date: Nov. 1, 2007

(54) Substrate processing method and apparatus

(76) Inventors: Akira Susaki, Tokyo (JP); Tsutomu Nakada, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 11/790,210

(22) Filed: Apr. 24, 2007

(30) Foreign Application Priority Data
Apr. 26, 2006 (JP) 2006-122600

(51) Int. Cl. H05K 3/36

(52) U.S. Cl. 29/830; 29/846; 29/847; 29/852

(57) ABSTRACT

A substrate processing method is useful for filling a hole formed in a substrate with conductive material. The substrate processing method includes forming a non-through hole in a substrate, and filling the non-through hole with conductive material by plating. The plating is performed using a plating solution containing solid particles.

### BACKGROUND OF THE INVENTION

1. Field of the Invention

The present invention relates to a substrate processing method and apparatus, and more particularly to a substrate processing method and apparatus useful for filling holes formed in a substrate with conductive material. The present invention also relates to a semiconductor device processed by such substrate processing method.

2. Description of the Related Art

As electronic equipment has become smaller equipment, higher processing speed, and lower power consumption in recent years, there has been a growing demand for high density connection between a semiconductor chip serving as a semiconductor device and a substrate or between the semiconductor chips. The semiconductor chip is hereinafter referred to as chip. Conventionally, a lead frame has been used for electrical connection between the chip and the substrate, and a wire bonding method for connecting a lead frame and a bonding pad on the chip by a gold wire or an aluminum wire has been widely used. Further, a Tape Carrier Package (TCP) in which projections of metal called bump are formed on the chip and are bonded to a film substrate having interconnects or a bare chip assembly in which bumps are bonded to a substrate or an interposer directly has been put to practical use. Further, the practical use of Multi Chip Package (MCP) or System In Package (SIP) in which a plurality of chips are laminated in a package has been progressing, and thus the bonding technology within the package has been becoming more important than before.

Wire bonding by gold wires or the like is mainly used for electrical connection in the package in the MCP or the SIP as heretofore. In this case, there are a method for connecting a bonding pad on a chip to a bonding pad on another chip via a lead frame and a method for connecting chips directly by wire bonding using a step formed by laminated chips having different sizes. Further, in particular, in order to connect two chips, a method for bonding bonding pads to each other by solder bump or the like with the surfaces of the chips facing each other is also used.

On the other hand, there has been developed a technology (through-via) for connecting interconnects of a plurality of laminated chips directly by way of through holes formed in the chips. In this technology, non-through holes are formed in the part of bonding pads of a semiconductor wafer having interconnect by a dry etching or a wet etching, and non-through holes are filled with conductive material (copper or the like), and then the semiconductor wafer is thinned from the backside of the semiconductor wafer by grinding, etching or the like to form through holes in the thin plate. The through holes in the thin plate are filled with conductive material (copper or the like), and the conductive material is directly connected to the bonding pad of the underlying chip in a vertical direction. This technology allows the size of the package to be equal to the size of the chip and enables high-density mounting, thus contributing to a smaller and lighter device. Further, because electrical coupling of the laminated chips is performed by way of the through holes, a spacing between the bonding pads can be smaller than before, thus making an area of the chip smaller. Although the bonding pad has been arranged on the peripheral portion of the chip from limitations of the wire bonding method, the bonding pad can be freely arranged in the chip. Thus, the degree of freedom of arrangement of interconnects in the chip can be improved, the length of the interconnects in the chip can be reduced, and chip performance such as processing speed or power consumption can be improved.

In the mounting method using such through-via, the depth of the non-through hole before producing the thin plate is required to be thicker than the thickness of the finished chip, and is thus in the range of several ten μm to several hundred μm, and the size of the rectangular non-through hole is several ten μm in each side. As a method for filling the non-through hole with metal interconnect material, there are an electroplating method, a CVD method, a PVD method, a reflow method, a conductive resin filling method, and the like. In these methods, the CVD method and the PVD method require a large-scale apparatus, and have disadvantages that the film formation speed is slow and productivity of filling a hole having a size on the order of several ten μm is low. The reflow method is performed by a simple apparatus, but has disadvantages that material is melted by reheating to cause deterioration of the material, local corrosion is caused by contact between interconnect material on the chip and different metal having a low melting point to lower reliability, and resistance becomes high due to formation of intermetalic compounds. In contrast, as compared to the CVD method and the PVD method, the electroplating method has advantages that the film formation speed is higher, the film of the same metal (copper) as interconnect on the chip can be formed, and the film having low resistance and high reliability can be formed.

Although the film formation speed in the electroplating method is higher than that in the CVD method and the PVD method, in the case where non-through hole having a diameter on the order of several ten μm is filled with conductive material by the electroplating method, the wafer is required to be plated for several hours to several ten hours. Therefore, a large-scale plating apparatus is required to ensure throughput capacity of the process, and a number of plating cells are required so as to cope with parallel processing, thus increasing manufacturing cost of the semiconductor device. Therefore, there is a need for a technology for filling non-through holes having such size with conductive material in a short period of time.

### SUMMARY OF THE INVENTION

The present invention has been made in view of the above drawbacks. It is therefore an object of the present invention to provide a substrate processing method and apparatus which can shorten processing time greatly when non-through hole formed in a substrate is filled with conductive material by a plating method, and can reduce manufacturing cost of a semiconductor device.

Another object of the present invention is to provide a semiconductor device which is produced by the above substrate processing method.

According to the present invention, a plating solution in which fine solid particles are dispersed is used to fill non-through holes having a diameter on the order of several ten μm with conductive material at high speed. When electroplating is performed using this plating solution, formation of a plated film and entrapment of solid particles by the plated film are simultaneously performed to increase the volume of the plated film.

The maximum growth rate of the plated film is limited by a critical current density determined mostly by composition of the plating solution. However, because the volume of the plated film is increased by entrapment of the solid particles in the plated film, the film-forming rate equal to or greater than the critical current density in apparent can be obtained. Further, by selecting the kind of solid particles suitably, the quality of the plated film and workability can be improved.

According to the present invention, a liquid in which fine solid particles are dispersed is used to fill non-through hole having a diameter on the order of several ten μm with conductive material at high speed. In this case, the non-through hole is filled with the solid particles by precipitation by gravity, centrifugal force or electrostatic force. Thereafter, electroplating is performed thereon, and thus the volume to be plated is decreased and filling the hole is quickly completed. Thus, processing time when the non-through hole is filled with conductive material can be greatly shortened.

According to a first aspect of the present invention, there is provided a substrate processing method comprising: forming a non-through hole in a substrate; and filling the non-through hole with conductive material by plating, wherein the plating uses a plating solution containing solid particles.

It is desirable that the non-through hole has a diameter of 10 μm to 500 μm and a depth of 10 μm to 500 μm. It is desirable that the solid particles have a diameter of 0.1 μm to 10 μm and occupy 1 to 90 vol % of the non-through hole.

In a preferred aspect of the present invention, a substrate processing method further comprises applying a force to the solid particles for introducing the solid particles into the non-through hole before the plating or during the plating.

It is desirable that the non-through hole has a diameter of 10 μm to 500 μm and a depth of 10 μm to 500 μm. It is desirable that the solid particles have a diameter of 0.1 μm to 10 μm and occupy 1 to 90 vol % of the non-through hole.

In a preferred aspect of the present invention, the applying the force to the solid particles comprises applying the force to the solid particles in a liquid such as pure water.

In the substrate processing method, after the non-through hole is filled with the solid particles, excess solid particles may be removed from the substrate. The removal of the solid particles may be performed using a spatula, a brush, a sponge, water flow, air flow or the like.

In a preferred aspect of the present invention, the applying the force comprises at least one of gravity, centrifugal force and electrostatic force.

In a preferred aspect of the present invention, the solid particles are dispersed in the plating solution. In a preferred aspect of the present invention, the solid particles are dispersed in the liquid such as pure water.

In a preferred aspect of the present invention, the solid particles comprise one of metal material, ceramic material and organic material.

Specifically, material of the solid particles comprises copper, silver, gold, platinum, alloy of these metal, compound of these metal, aluminum oxide, titanium oxide, silicon oxide, cerium oxide, polytetrafluoroethylene, polycarbonate, polystyrene, polyvinyl alcohol, polyimide, graphite, carbon fiber or carbon black.

In a preferred aspect of the present invention, the plating solution in which the solid particles are dispersed contains cationic surfactant. In a preferred aspect of the present invention, the liquid in which the solid particles are dispersed contains cationic surfactant.

The cationic surfactant preferably contains at least one of alkyl trimethyl ammonium chloride, dialkyl dimethyl ammonium chloride, alkyl dimethyl benzyl ammonium chloride, alkyl pyridinium chloride and these derivatives. It is desirable that the concentration of cationic surfactant is not more than critical micelle concentration.

According to a second aspect of the present invention, there is provided a substrate processing apparatus comprising: a plating apparatus for plating a substrate having a non-through hole using a plating solution to fill the non-through hole with conductive material, wherein the plating solution contains solid particles.

The plating solution preferably comprises one of a copper plating solution, a silver plating solution, a gold plating solution, a tin plating solution, and an alloy plating solution of these metals. The solid particles preferably comprise copper, silver, gold, platinum, alloy of these metal, compound of these metal, aluminum oxide, titanium oxide, silicon oxide, cerium oxide, polytetrafluoroethylene, polycarbonate, polystyrene, polyvinyl alcohol, polyimide, graphite, carbon fiber or carbon black. It is desirable that the solid particles have a diameter of 0.1 μm to 10 μm.

In a preferred aspect of the present invention, a substrate processing apparatus further comprises a concentration measuring device for measuring concentration of the solid particles.

It is desirable that the concentration measuring device measures the concentration of solid particles by detecting transmittance of light or detecting the density of the plating solution. Further, a concentration adjustment device may be provided to adjust the concentration of solid particles on the basis of the measured results by the concentration measuring device.

In a preferred aspect of the present invention, a substrate processing apparatus further comprises a surface tension measuring device for measuring surface tension of the plating solution. The surface tension measuring device measures the surface tension of the plating solution by a sessile drop method, a bubble pressure method, a wilhelmy method or a pendant drop method.

A concentration adjustment device may be preferably provided to adjust the concentration of surfactant or the concentration of solid particles in the plating solution on the basis of the measured results by the surface tension measuring device.

According to a third aspect of the present invention, there is provided a substrate processing apparatus comprising: a mechanism configured to introduce solid particles into a non-through hole of a substrate; and a plating apparatus for plating the substrate using a plating solution to fill the non-through hole with conductive material.

The substrate processing apparatus may further comprise a solid particle removing mechanism for removing excess solid particles from the substrate. The solid particle removing mechanism may comprise a spatula, a brush, a sponge, a water flow supply device, or an air flow supply device. Further, the substrate processing apparatus may further comprise a substrate storage mechanism for storing the substrate in a liquid.

In a preferred aspect of the present invention, the mechanism configured to introduce the solid particles into the non-through hole comprises one of a centrifugal mechanism, a precipitation tank and an electrophoresis tank.

According to a fourth aspect of the present invention, there is provided a semiconductor device comprising: a substrate; a non-through hole formed in the substrate; a conductor formed in the non-through hole; and solid particles included in the conductor, wherein the solid particles comprises the same material as the conductor or different material from the conductor.

According to the present invention, the processing time when a hole having a diameter of several ten μm formed in a substrate is filled by a plating method can be shortened greatly, manufacturing cost of a semiconductor device can be reduced, and high reliability of the semiconductor device can be achieved.

### BRIEF DESCRIPTION OF THE DRAWINGS

FIGS. 1A through 1C are schematic views showing the state in which filling a non-through hole is performed using a plating solution containing solid particles, and FIGS. 1D through 1F are schematic views showing the state in which filling a non-through hole is performed using a plating solution containing no solid particles;

FIGS. 2A through 2C are schematic views showing the state in which filler adheres to a plated film on a substrate in the case of using conductive filler;

FIGS. 3A through 3F are schematic views showing the state in which filler adheres to a plated film on a substrate in the case of using conductive filler;

FIGS. 4A through 4C are schematic views showing the state in which filler adheres to a plated film on a substrate in the case of using non-conductive filler;

FIG. 5 is a view showing the relationship between the concentration of surfactant and surface tension;

FIG. 6 is a schematic view showing a substrate processing apparatus according to an embodiment of the present invention;

FIG. 7 is a view showing comparison of the thickness of a plated film in the case of the presence or absence of filler;

FIGS. 8A and 8B are views showing basic principle of an increase of the volume of a plated film and speeding-up of formation of the plated film using a filling solution of solid particles;

FIGS. 9A through 9F are schematic views showing an example of plating process of the substrate using solid particles;

FIG. 10 is a schematic view showing a substrate processing apparatus according to another embodiment of the present invention;

FIG. 11 is a schematic view showing the procedure performed in the plating tank;

FIG. 12 is a schematic view showing the procedure performed in the plating tank;

FIG. 13 is a schematic view showing the procedure performed in the plating tank;

FIG. 14 is a schematic view showing the procedure performed in the plating tank;

FIG. 15 is a schematic view showing the procedure performed in the plating tank;

FIG. 16 is a schematic plan view showing a substrate processing apparatus having a solid particle filling mechanism for filling non-through hole with filler by a centrifugal mechanism;

FIG. 17 is a schematic side cross-sectional view showing a substrate processing apparatus having a solid particle filling mechanism for filling non-through hole with filler by a centrifugal mechanism;

FIG. 18 is a schematic view showing a substrate processing apparatus according to still another embodiment of the present invention;

FIG. 19 is a view showing comparison of the thickness of the plated film depending on the presence or absence of filler and placement conditions of the substrate; and

FIG. 20 is an enlarged schematic cross-section view showing the state of the plated film formed in non-through hole depending on the presence or absence of filler.

### DETAILED DESCRIPTION OF THE PREFERRED EMBODIMENTS

### FIRST INVENTION

A substrate processing method and apparatus according to a first invention will be described below with reference to drawings. In the first invention, a plating solution in which fine solid particles are dispersed is used to fill non-through holes having a diameter on the order of several ten μm with conductive material at high speed. When electroplating is performed using this plating solution, formation of a plated film and entrapment of solid particles by the plated film are simultaneously performed to increase the volume of the plated film. Thus, processing time when the non-through hole is filled with conductive material can be greatly shortened.

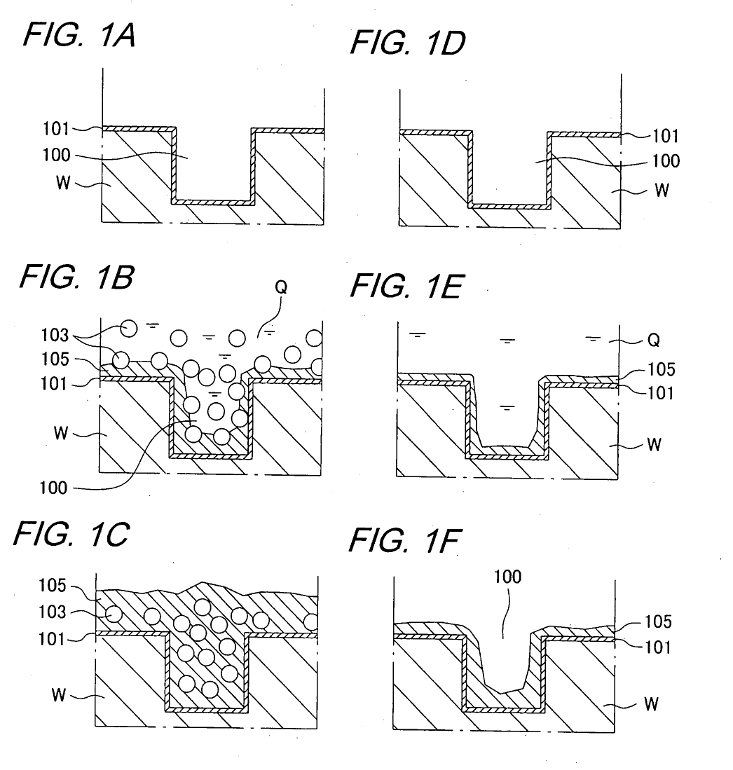

FIGS. 1A through 1F are schematic views showing the state in which filling a non-through hole is performed using a plating solution containing solid particles in comparison with the state in which filling a non-through hole is performed using a conventional plating solution containing no solid particles. FIGS. 1A through 1C show the state in which filling anon-through hole is performed using a plating solution containing solid particles, and FIGS. 1D through 1F show the state in which filling of a non-through hole is performed using a plating solution containing no solid particles. As shown in FIG. 1A, a seed layer 101 is formed on an inner surface of a non-through hole 100 and a surface of a substrate W. As shown in FIG. 1B, the electroplating is performed on the substrate W having the seed layer 101 using a plating solution Q containing solid particles (filler) 103, and formation of a plated film 105 and entrapment of the solid particles 103 by the plated film 105 are simultaneously performed, thus increasing the volume of the plated film 105 as shown in FIG. 1C.

In contrast, in the case where the electroplating is performed using a plating solution containing no solid particles under the same conditions as the above, the volume of the plated film 105 is not increased as compared with the case in which the electroplating is performed using the plating solution Q containing the solid particles (filler) 103. Thus, the processing time when the non-through hole 100 is filled with conductive material is prolonged.

It is desirable that the non-through hole 100 has a diameter (a side in the case of square) of 10 μm to 500 μm and a depth of 10 μm to 500 μm. Further, the solid particles 103 preferably contain metal (copper, silver, gold, platinum, alloy of these metals or compound of these metals), aluminum oxide, titanium oxide, silicon oxide, cerium oxide, polytetrafluoroethylene (PTFE), polycarbonate, polystyrene, polyvinyl alcohol, polyimide, graphite, carbon fiber or carbon black. Further, it is desirable that the solid particles 103 have a diameter of 0.1 μm to 10 μm and occupy 1 to 90 vol % of the non-through hole 100, and the plating solution Q contains cationic surfactant. Next, elements of the present invention will be described in detail.

The substrate W such as a semiconductor wafer has a surface in which the non-through hole 100 is formed, and the surface of the substrate W is composed mainly of a dielectric film such as SiO₂ or SiN and a silicon substrate and partly of conductive material such as copper or aluminum. Particularly, the inner wall and the bottom surface of the non-through hole are composed of the silicon substrate, and thus formation of a film by the electroplating cannot be performed as they are. Therefore, a dielectric layer (barrier layer) is formed suitably, and then a conductive layer (seed layer) 101 is formed on the surface of the substrate and the interior of the non-through hole 100. Then, the electroplating is performed on the conductive layer 110. The conductive layer 101 comprising copper or the like is formed by an evaporation method, a sputtering method or a CVD method. When the conductive layer 101 is formed, processing conditions are adjusted so as to form the conductive layer on the sidewall of the non-through hole 100.

The plated film 105 for filling the non-through hole 100 comprises a copper plated film, a silver plated film, a gold plated film, a tin plated film, a solder plated film or a substitution solder plated film. The copper plated film is used for an interconnect layer of a printed wiring board or a semiconductor chip, and the copper plated layer has excellent adhesiveness and corrosive resistance. Further, in the copper plating process, the relationship among liquid composition, the plating conditions and the quality of film has been made clear as interconnect layer material, and filling the non-through hole 100 has been widely studied. Thus, application of such relationship or such filling to the present invention can be easily performed. On the other hand, although silver plating and gold plating are more expensive than copper plating, the plated film 105 having a low resistance can be formed, and therefore the silver plating and the gold plating are useful for high-speed devices which should avoid a problem of signal delay between chips or devices which require low power consumption. In the case of solder plating or substitution solder plating, it is possible to bond chips only by heating the chips in piles, thus simplifying the bonding process. However, in general solder plating, after packaging, the inside of the through hole is melted by heating when the chip is mounted on the substrate, and hence it is necessary to adjust composition of material and use the material having higher melting point than that of solder used for the substrate.

As the kind of the solid particles (hereinafter referred to as filler) 103 dispersed in the plating solution Q, there are metal material such as copper powder, silver powder or gold powder, ceramic material such as Al₂O₃ power, SiO₂ powder, CeO₂ powder or TiO₂ powder, or organic material such as polyimide powder or fluorocarbon resin powder. The filler 103 is mostly precipitated, aggregated or drifted in the plating solution Q, and therefore surfactant, particularly cationic surfactant as dispersant for dispersing the filler 103 in the plating solution Q is used. As cationic surfactant, at least one of alkyl trimethyl ammonium chloride, dialkyl dimethyl ammonium chloride, alkyl dimethyl benzyl ammonium chloride, alkyl pyridinium chloride and these derivatives is used. When the filler 103 adsorbs cationic surfactant, the surface of the filler 103 is positively charged, and thus the filler 103 is attracted to the surface of the substrate W serving as a negative electrode by an electrostatic force during the electroplating to adhere to the surface of the substrate W. At the same time, electrolysis of the plating solution Q progresses, and the plated film 105 grows so as to enclose the adhering filler 103. As a result, the plated film 105 containing the filler 103 is formed.

In the case where the filler 103 is filled into the non-through hole 100, it is necessary that the particle diameter of the filler 103 is smaller than the inner diameter of the non-through hole 100 to a certain degree. In particular, in order to spread the filler 103 over the bottom surface of the non-through hole 100, the upper limit of the filler 103 is about one third of the inner diameter of the hole. Further, the particle diameter of the filler 103 has an effect on dispersion of the filler 103 in the plating solution Q. If the particle diameter of the filler 103 is large, the filler 103 is liable to be precipitated, and thus intense stirring is required to disperse the filler 103 uniformly in the plating solution Q. However, if stirring is too intense, the filler 103 is difficult to fix to the substrate W. Further, the filler 103 impinges on the substrate W to cause exfoliation or damage to the substrate W, resulting in a defective product. If the particle diameter of the filler 103 is too small, the filler 103 is liable to be dissolved completely by corrosiveness of the plating solution Q. Further, it is feared that the filler 103 is aggregated in the plating solution Q, the gap between the filler 103 becomes narrow at the time of filling, and filling capability of the plated film 105 becomes deteriorated. Therefore, the particle diameter of the filler is preferably in the range of about 0.1 μm to about 10 μm. In addition, if particle size distribution is large, moving speed of the particles varies due to flow velocity, and thus the particle diameter differs depending on the location of the substrate W. Therefore, it is desirable that particles of the filler 103 should be classified to some degree.

### [In the Case of Using Conductive Filler]

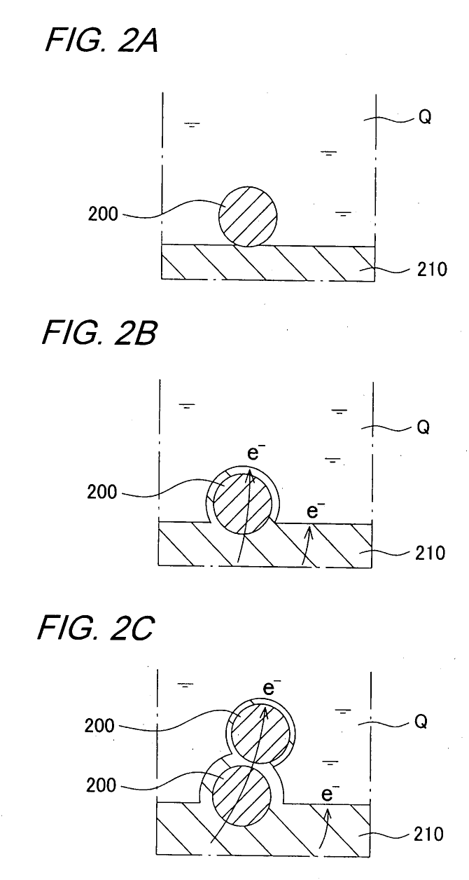

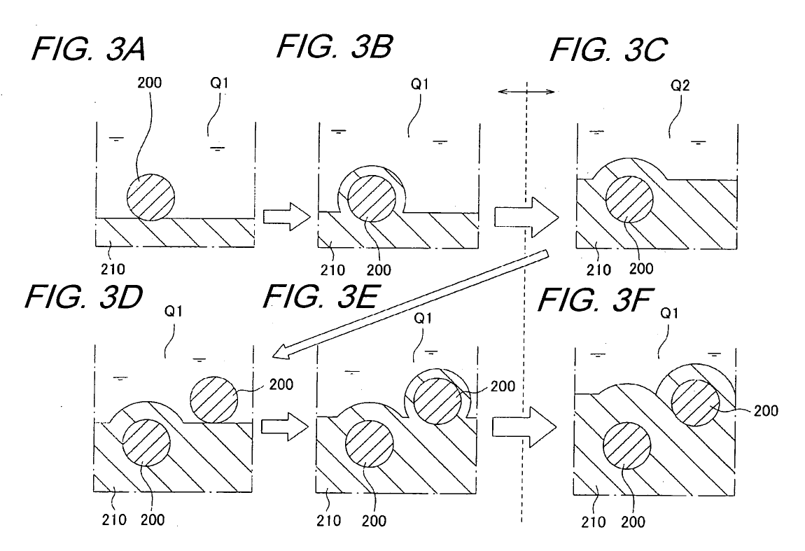

Even if metal filler (conductive material) such as Cu powder, Ag powder or Au powder is entrapped in the plated film, such filler does not increase electrical resistance, and hence such filler is most suitable for material for filling the non-through hole. Further, if the same metal as the plated film is used for the filler, deterioration caused by the difference of thermal expansion coefficient hardly occurs. However, as shown in FIG. 2A, if metal filler 200 is dispersed in the plating solution Q, the surface of the filler 200 becomes an electrode at the same time that the filler 200 adheres to the plated film 210 on the substrate, thus causing electrolysis. Therefore, a film is formed also on the surface of the filler 200 as shown in FIG. 2B, and the filler 200 is coupled to each other as shown in FIG. 2C to become sparse structure. Thus, a smooth plated film 210 cannot be produced. Therefore, in order to reduce unevenness of the plated film, there is a method in which adhesion of the filler to the substrate and formation of the film by plating are carried out by discrete processes. Specifically, as shown in FIGS. 3A and 3B, electroplating is performed on the plated film 210 on the substrate in a first plating solution Q1 containing metal filler 100. In this state, a new thin plated film 210 is formed on the plated film 210 to which the filler 200 adheres, thus causing large unevenness of the surface of the substrate. Next, as shown in FIG. 3C, plating is performed in a second plating solution Q2 containing no filler 200, thereby smoothing the unevenness of the surface of the substrate. It is desirable that the concentration of the additives in the second plating solution Q should be adjusted to promote filling capability of unevenness and smoothing of the surface of the substrate. Further, in the case where the size of the non-through hole is large as shown in FIGS. 3D to 3F, the plating processes using two kinds of the plating solutions Q1 and Q2 are alternately performed repeatedly to form a smooth plated film 210 at high speed.

### [In the Case of Using Non-Conductive Filler]

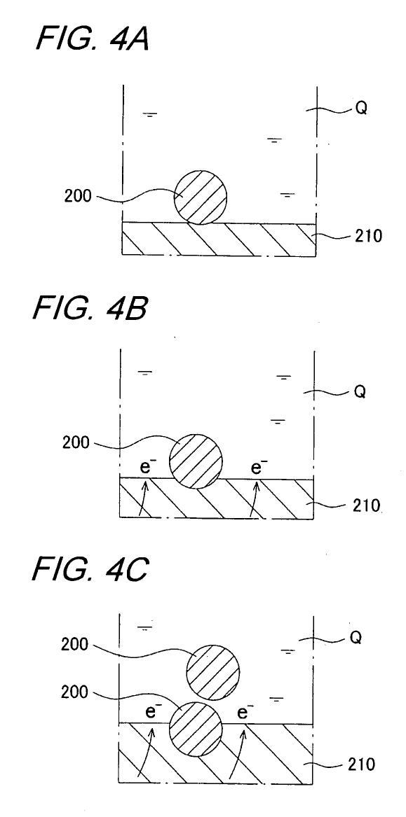

In the case of using ceramic, organic, or other non-conductive filler, the non-through hole has higher resistance than that in metal filler. However, as shown in FIGS. 4A through 4C, even if the filler 200 adheres to the plated film 210 on the substrate during plating, electrolysis does not take place on the surface of the filler 200, and therefore a film is formed only on the surface of the plated film 210 to cause the filler 200 to be buried gradually, thus achieving relatively smooth embedding. Further, in the case where metal filler different from material of the plated film 210 is used, the metal filler is liable to be corroded by the effect of local cell. However, dielectric filler is not corroded at all. Since there is a large difference in hardness between ceramic or organic filler and metal filler, local distribution of hardness is formed on the surface of the bonding portion by embedding. In this state, when such chip and other chip are directly contacted and rubbed, surface oxide film on the facing surfaces of the chips are broken each other by the difference of hardness, thus improving reliability after bonding.

Next, the concentration of the filler entrapped in the plated film is determined by the balance between the growth rate of the plated film and the amount of adhesion of the filler to the surface of the electrode. Therefore, supply of the filler to the surface of the electrode, i.e. the flow of the plating solution on the surface of the electrode is important. Further, when plating progresses, the filler in the plating solution is entrapped in the plated film near the electrode, and thus a layer (diffusion layer) having a lower filler concentration is formed. In order to supplement the lowered concentration of the filler in the diffusion layer, it is necessary to supply the filler by stirring. On the other hand, if stirring is too intense, the particles of the filler adhering to the surface of the electrode are removed from the surface of the electrode to reduce the amount of the filler entrapped in the plated film. Consequently, the growth rate of the film cannot be increased. Since the filler having a low density such as PTFE (polytetrafluoroethylene) is liable to be influenced by the flow of the plating solution, stirring should be suppressed as much as possible. As to other filler, it is necessary that the flow of the plating solution should be suppressed to cause the filler to be entrapped by the plated film reliably and the distribution of the flow of the plating solution should be uniformized over the surface of the substrate. Specifically, it is effective that the concentration of the filler in the plating solution is increased and the thickness of the diffusion layer is made smaller, and mild flow of the plating solution is produced on the surface of the substrate. However, since steady flow of the plating solution tends to cause surface distribution due to particle size distribution of the filler or the like, it is desirable to disturb the flow of the plating solution suitably.

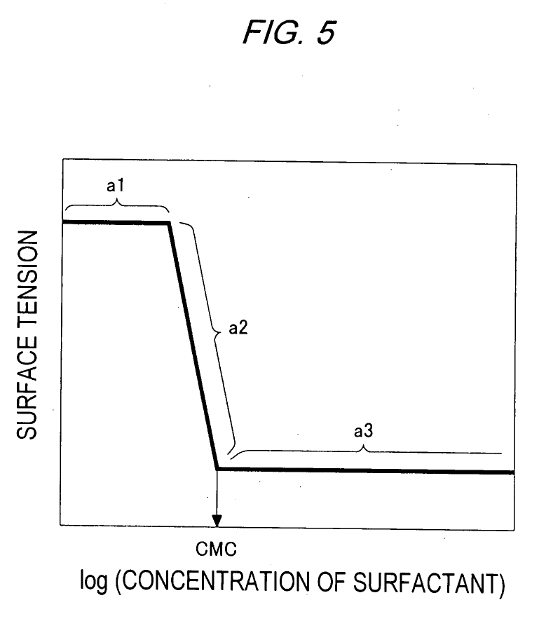

The amount of surfactant required for dispersing the filler in the plating solution is determined by the amount of the filler, the kind of the filler, and the kind of the surfactant. As hydrophobic property of filler is higher, a large amount of surfactant required becomes larger. Because the concentration of the surfactant has a great effect on structure of the plated film, excess addition of the surfactant should be avoided. The amount of the surfactant to be added is determined by the surface tension of the plating solution. Specifically, the filler is added to the plating solution, and the surface tension is then measured while the surfactant is gradually added to the plating solution. As shown in FIG. 5, as the concentration of the surfactant is increased, the surface tension of the plating solution is kept at a constant value for a while, and is then gradually lowered. When the concentration of the surfactant exceeds a certain value, the surface tension of the plating solution becomes constant again. It is considered that even if the surfactant is added to the plating solution in the low concentration range of the surfactant, the added surfactant is adsorbed on the surface of the filler and is consumed in the range a1 in which the surface tension is not lowered, and the surfactant adheres to the interface between the plating solution, gaseous phase and a container in the range a2 in which the surface tension is lowered. The range a3 in which the surface tension becomes constant again is a concentration range in which the surfactant in the plating solution forms micelle, and the concentration of the surfactant at inflection point immediately before becoming constant is called critical micelle concentration (CMC). The amount of the added surfactant is not more than CMC, and is equal to the value immediately before the surface tension stars to be lowered, whereby dispersibility of the filler is ensured and the effect of addition of the surfactant on the structure of the plated film can be suppressed.

On the other hand, since particles such as Al₂O₃ have hydrophilic surfaces, and surface potential in the acid plating solution is positive, such particles can be dispersed in the plating solution without using surfactant. In this case, only filler is added to the plating solution and only stirring is performed.

If the plating solution containing the filler is repeatedly used, metal ions (for example, copper ions), additives, filler, and surfactant are changed in amount. Therefore, it is necessary that the concentration of filler and the concentration of surfactant are monitored and adjusted as needed. Because the filler is generally opaque, the concentration of the filler can be obtained by measuring absorbance of the plating solution. Specifically, an absorption spectrometer is provided in a plating cell or a pipe for a plating solution to monitor a change of absorbance. When the absorbance is lowered to a certain value or less by decrease of the amount of filler, the filler is added to restore the concentration of the filler. In order to add the filler to the plating solution, dense filler dispersion to which surfactant is added maybe used, or the filler and the surfactant may be separately added to the plating solution.

As another method for obtaining the concentration of the filler in the plating solution, there is a method in which a certain amount of the plating solution is sampled and the density of the plating solution is measured. This method is effective in the case where the filler having a large specific gravity such as metal filler is used or the case where concentration of the plating solution which contains a large amount of filler to allow light to hardly pass through is controlled.

The amount of the surfactant can be controlled by monitoring surface tension of the plating solution. When the filler is consumed by plating, part of the surfactant which adheres to the surface of the filler is released in the plating solution to lower the surface tension of the plating solution. The surface tension may be obtained by a simple method such as a sessile drop method (surface tension is obtained from the balance between droplet weight and the surface tension) or a bubble pressure method (surface tension is obtained from maximum pressure of bubbles generated from a pipe in the liquid). Further, as other method for measuring surface tension, a wilhelmy method and a pendant drop method are enumerated. The surface tension is monitored in the plating tank, a separate tank or the like using a device for measuring surface tension of the plating solution by these methods, and the filler is added so as to balance excess amount of surfactant. Thus, surfactant adsorbs the filler, and the change of the plated film in quality can be suppressed.

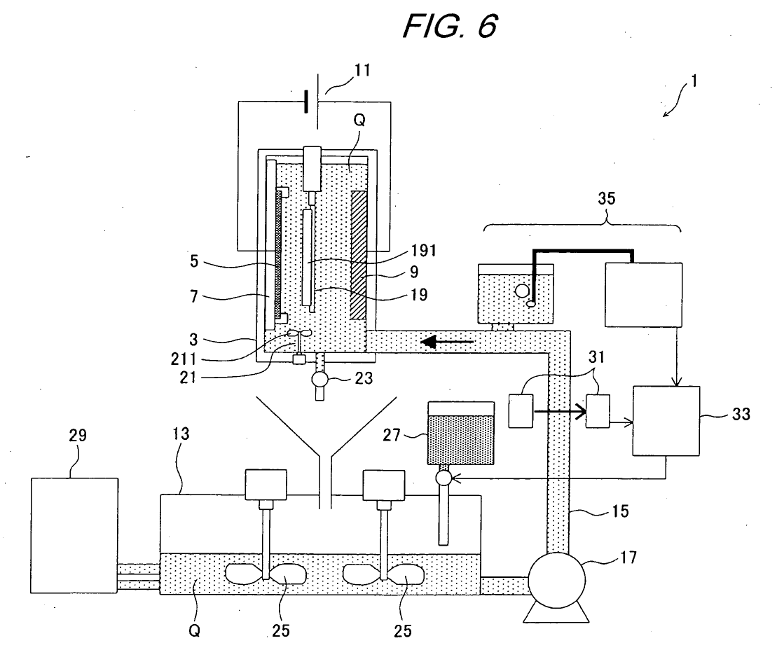

FIG. 6 is a schematic view showing an example of a substrate processing apparatus for performing a substrate processing method according to an embodiment of the present invention. As shown in FIG. 6, a substrate processing apparatus 1 comprises a plating tank 3 having a plating solution Q therein, a substrate holder 7 provided in the plating tank 3 for holding a substrate 5, a counter electrode (anode) 9 provided so as to face the substrate 5, an electric supply 11 connected to the substrate 5 and the counter electrode (anode) 9, and a pump 17 connected to a plating solution supply tank 13 through a pipe 15 for supplying the plating solution Q to the plating tank 3. An agitator 19 is disposed so as to face the surface (surface to be plated) of the substrate 5 in the plating tank 3, and an agitator 21 is disposed at the lower part of the plating tank 3. The plating solution Q comprises a plating solution to which the filler is added. The agitator 19 has a bar-like paddle 191 vertically disposed in the plating tank 3, and the paddle 191 is translated in a direction perpendicular to the sheet of FIG. 6 near the surface of the substrate 5 to stir the plating solution Q. The agitator 21 has a brade 211, and the brade 211 is rotated to stir the plating solution Q. A drain 23 is provided at the bottom of the plating tank 3 to return the plating solution Q in the plating tank 3 to the plating solution supply tank 13. The agitators 25, 25 for stirring the plating solution Q are disposed in the plating solution supply tank 13. Further, a filler storage tank (concentration adjustment means) 27 for replenishing the filler to the plating solution Q and a plating solution analyzer 29 for measuring the amount of metal ions and the amount of various additives in the plating solution Q and replenishing decreased composition as needed are connected to the plating solution supply tank 13, respectively. An absorption spectrometer (means for measuring concentration of solid particles) 31 and a surface tension measuring device (means for measuring surface tension) 35 are disposed in the pipe 15, and output signals of the absorption spectrometer 31 and the surface tension measuring device 35 are inputted into a filler concentration measuring device 33.

In the substrate processing apparatus 1 thus constructed, current is caused to flow between the substrate 5 and the counter electrode (anode) 9 to perform electroplating on the surface of the substrate 5. On the other hand, the filler is supplied to the surface of the substrate 5 by agitation of the agitators 19, 21. The plating solution Q in the plating tank 3 is discharged through the drain 23 and stored in the plating solution supply tank 13. In the plating solution supply tank 13, stirring is performed suitably by the agitators 25 to suppress precipitation of the filler. In the plating solution analyzer 29, as described above, the amount of metal ions and the amount of various additives in the plating solution Q are measured and decreased composition is replenished as needed. The plating solution Q in the plating solution supply tank 13 is supplied to the plating tank 3 by the pump 17, and the concentration of the filler in the plating solution Q is detected by the absorption spectrometer 31 and the concentration of the surfactant is detected by the surface tension measuring device 35 while the plating solution Q is being supplied. These detection results are computed by the filler concentration measuring device 33, and the amount of the filler required is replenished from the filler storage tank 27 to the plating solution supply tank 13 on the basis of the output signals from the filler concentration measuring device 33 to adjust the concentration of the solid particles in the plating solution Q.

### SECOND INVENTION

A substrate processing method and apparatus according to a second invention will be described below with reference to drawings. In the second invention, a plating solution in which fine solid particles are dispersed is used to fill non-through holes having a diameter on the order of several ten μm with the solid particles at high speed. Thereafter, electroplating is performed thereon, and thus the volume to be plated is decreased and filling the hole is quickly completed. Therefore, processing time when the non-through hole is filled with conductive material can be greatly shortened.

FIGS. 8A and 8B are views showing basic principle of an increase of the volume of a plated film and speeding-up of formation of the plated film using a filling solution of the solid particles. The solid particles (filler) 301 dispersed in a liquid (filling liquid) 300 are deposited on the surface of the substrate W by gravity, centrifugal force and electrostatic force or the like. Thereafter, plating is performed thereon to cause the solid particles 301 to be entrapped in a plated film 303. Thus, the volume of the plated film 303 is equal to the sum of the volume of the solid particles 301 and the volume of deposited metal. Therefore, the thickness of the plated film 303 becomes thicker by the volume of the entrapped solid particles 301 than the case where the solid particles 301 are not used, and thus the growth rate of the plated film 303 becomes high.

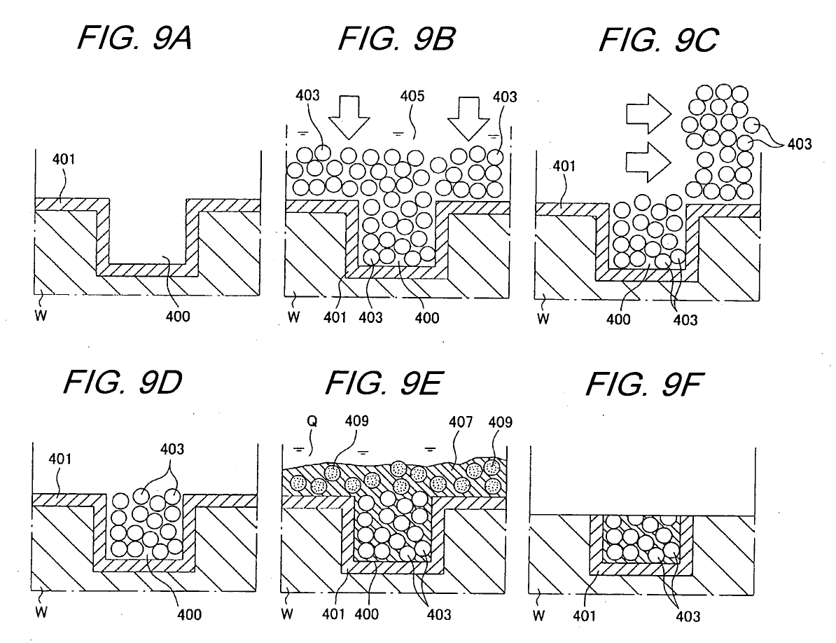

FIGS. 9A through 9F are schematic views showing an example of processing of the substrate according to the present invention. As shown in FIG. 9A, a seed layer 401 is formed on an inner surface of a non-through hole 400 and a surface of a substrate W. Then, the substrate W is disposed so as to direct the seed layer 401 upward, and a filling liquid 405 in which solid particles (filler) 403 are dispersed is put on the seed layer 401 of the substrate W and is allowed to stand as shown in FIG. 9B. After a while, the solid particles 403 are precipitated by specific gravity to cover the entire surface of the substrate W including the interior of the non-through hole 400. Thereafter, the substrate W is taken out from the filling liquid 405 (the substrate may not be necessarily taken out), the surface of the substrate W is rubbed by a solid particle removing mechanism such as a spatula or a sponge to remove excess solid particles 403. Thus, the solid particles 403 are left only in the interior of the non-through hole 400 as shown in FIG. 9D. Then, the substrate W is put into the plating tank, and is soaked in the plating solution Q, thereby performing plating of the substrate W. At this time, a plated film 407, being formed, entraps the solid particle 403 and grows, and thus the non-through hole 400 is filled with the solid particles 403 and the plated film 407. On the other hand, although the plated film 407 grows also on the surface of the substrate W, most of such plated film 407 is unnecessary in the subsequent process, and thus such plated film is required to be removed as shown in FIG. 9F (if such plated film is not required to be removed, it may be used as it is). In order to remove the excess plated film 407 on the surface of the substrate W, chemical mechanical polishing (CMP), chemical etching, plasma etching, or the like is used. In the case of using chemical mechanical polishing (CMP) or chemical etching, processing conditions should be determined in consideration of solubility of both of the plated film 407 and the solid particles 403, polishing rate, and generation of corrosion caused by electric potential difference between the solid particles 403 and the plated film 407. Further, if the excess plated film 407 is thick, the processing time and the cost of consumed material are increased, and thus removal of such excess plated film 407 should be easily performed. Therefore, in this example, as shown in FIG. 9E, when the plated film 407 is formed, the plating solution Q in which soft material such as PTFE is dispersed as solid particles (filler) 409 is used to perform plating. Before this plating, since the non-through hole 400 has been filled with the solid particles 403, the soft solid particles 409 hardly enter the interior of the non-through hole 400. On the other hand, since the soft solid particles 409 are dispersed and entrapped in the plated film 407 on the surface of the substrate W, time for formation of the film can be shortened. Because the soft solid particles 409 are easily deformed and removed during polishing by the CMP, the polishing rate of the plated film 407 can be increased and removal of the excess plated film 407 can be speeded up.

It is desirable that the non-through hole 400 has a diameter (a side in the case of square) of 10 μm to 500 μm and a depth of 10 μm to 500 μm. Further, the solid particles 403 preferably contain metal (copper, silver, gold, platinum, alloy of these metal or compound of these metal), aluminum oxide, titanium oxide, silicon oxide, cerium oxide, polytetrafluoroethylene (PTFE), polycarbonate, polystyrene, polyvinyl alcohol, polyimide, graphite, carbon fiber or carbon black. Further, it is desirable that the solid particles 403 have a diameter of 0.1 μm to 10 μm and occupy 1 to 90 vol % of the non-through hole 400, and the plating solution Q contains cationic surfactant. Next, elements of the present invention will be described in detail.

As described in the first invention, the plated film 407 for filling the non-through hole 400 comprises a copper plated film, a silver plated film, a gold plated film, a tin plated film, a solder plated film or a substitution solder plated film. The properties of the above metals are the same as those described in the first invention.

As the kind of the solid particles (hereinafter referred to as filler) 403 for filling the non-through hole 400, there are metal material such as copper powder, silver powder or gold powder, ceramic material such as Al₂O₃ powder, SiO₂ powder, CeO₂ powder or TiO₂ powder, or organic material such as polyimide powder, fluorocarbon resin powder, silicon powder, or carbon powder. The filler 403 is mostly precipitated, aggregated or drifted in the filling liquid 405, and therefore surfactant for dispersing the filler 403 in the filling liquid 405 is used as needed. At this time, the concentration of surfactant is determined by the amount of the filler 403, the kind of the filler 403, and the kind of the surfactant. As hydrophobic property of the filler 403 is higher, the amount of surfactant required becomes larger. Because the concentration of the surfactant has a great effect on structure of the plated film 407, excess addition of the surfactant should be avoided. The amount of the added surfactant is not more than critical micelle concentration (CMC), and is equal to the value immediately before the surface tension starts to be lowered, whereby dispersibility of the filler is ensured and the effect of addition of the surfactant on the substrate W can be suppressed.

As a solvent for the filling liquid 405 for dispersing the filler 403, there are pure water, alcohol having a low boiling point, a plating solution, and the like. Pure water can be easily handled and has a little influence on the filler 403, but metal filler such as conductive layer or copper is liable to be oxidized by dissolved oxygen. Further, if the filler 403, which has been filled, having water remaining thereon is supplied to the plating process, the plating solution Q is diluted in the non-through hole 400, and thus filling the hole by the plated film 407 is hindered. Alcohol having a low boiling point such as methanol, ethanol, or propanol has a smaller effect on conductive layer or copper than pure water. Further, since alcohol having a low boiling point can be easily evaporated by heating or decompression, an effect on dilution of the plating solution Q can be suppressed. However, because facilities for heating, exhaust, removal of harmful substance, and the like are required to cause overall system to be large-scale.

If a plating solution used for the subsequent process is used as a solvent, after filling of the filler 403, the plating can be performed without removing the plating solution, and hence there is no fear of dilution of the plating solution in the non-through hole 400. Thus, the plating solution can be easily handled. However, an effect of dissolution or corrosion of the filler 403 or the conductive layer caused by the plating solution should be considered, and thus it is important that plating should be performed immediately after filling of the filler 403.

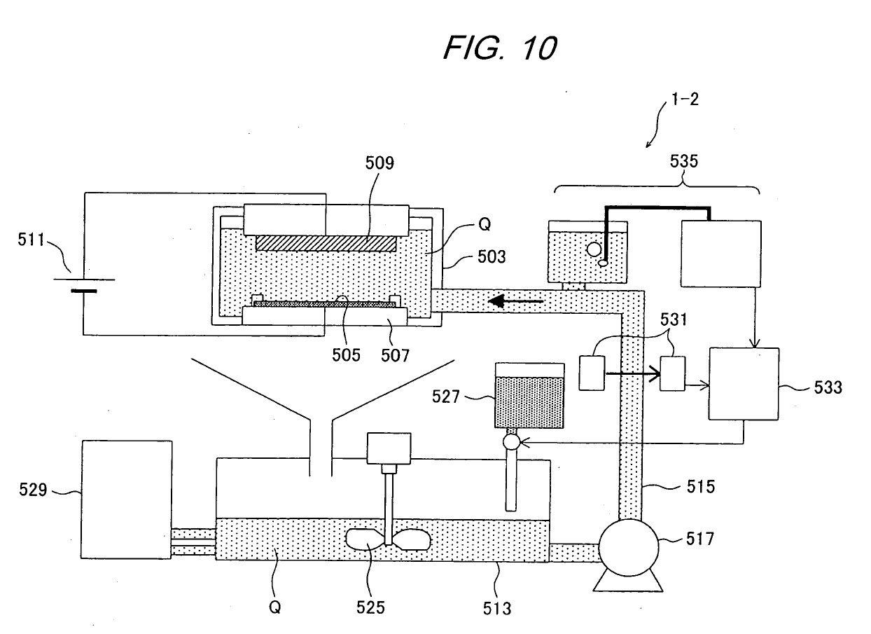

FIG. 10 is a schematic view showing an example of a substrate processing apparatus for performing a substrate processing method according to an embodiment of the present invention. In this example, a filling liquid prepared by dispersing the filler in the plating solution Q is used, the non-through hole is filled with the filler by precipitation, and then plating is performed to form a conductive layer in the non-through hole and on the surface of the substrate. However, filling of the filler and plating may be performed by different liquids depending on the structure of the apparatus and the processing method.

As shown in FIG. 10, a substrate processing apparatus 1-2 comprises a plating tank 503 (serving also as solid particle filling mechanism) having a filling liquid (hereinafter referred to as plating solution) Q therein, a substrate holder 507 provided in the plating tank 503 for holding a substrate 505, a counter electrode (anode) 509 provided so as to face the substrate 505, an electric supply 511 connected to the substrate 505 and the counter electrode (anode) 509, and a pump 517 connected to a plating solution supply tank 513 through a pipe 515 for supplying the plating solution Q to the plating tank 503. The substrate 505 to be processed is placed on the substrate holder 507 so as to direct the surface (the surface to be processed) upward in the plating tank 503. An agitator 525 is disposed in the plating solution supply tank 513 to stir the plating solution Q. Further, a filler storage tank (concentration adjustment means) 527 for replenishing the filler to the plating solution Q and a plating solution analyzer 529 for measuring the amount of metal ions and the amount of various additives in the plating solution Q and replenishing decreased composition as needed are connected to the plating solution supply tank 513, respectively. An absorption spectrometer (means for measuring concentration of solid particles) 531 and a surface tension measuring device (means for measuring surface tension) 535 are disposed in the pipe 515, and output signals of the absorption spectrometer 531 and the surface tension measuring device 535 are inputted into a filler concentration measuring device 533.

In the substrate processing apparatus 1-2 thus constructed, the plating solution Q containing the filler is stored in the plating solution supply tank 513, and is supplied to the plating tank 503 by the pump 517. In the plating solution supply tank 513, in order to avoid dispersion of the concentration caused by precipitation of the filler and generation of aggregation, the plating solution Q is stirred suitably by the agitator 525. Since the concentration of the filler in the plating solution Q is lowered by repeated processing, control of the concentration of the filler is required. The concentration of the filler in the plating solution Q supplied to the plating tank 503 by the pump 517 is detected by measuring transmittance of light by the absorption spectrometer 531 and the concentration of the surfactant is detected by the surface tension measuring device 535 while the plating solution Q is being supplied. The amount of the filler consumed is computed by the filler concentration measuring device 533 on the basis of these detection results, and the amount of the filler required is replenished from the filler storage tank 527 to the plating solution supply tank 13 by the output signals from the filler concentration measuring device 533 to adjust the concentration of the solid particles in the plating solution Q. In the filler storage tank 527, in addition to the filler and surfactant, for example, a dense plating solution may be held, and composition of the plating solution may be also supplied. Various compositions such as additives in the plating solution Q are analyzed by the plating solution analyzer 529 and insufficient component is suitably replenished.

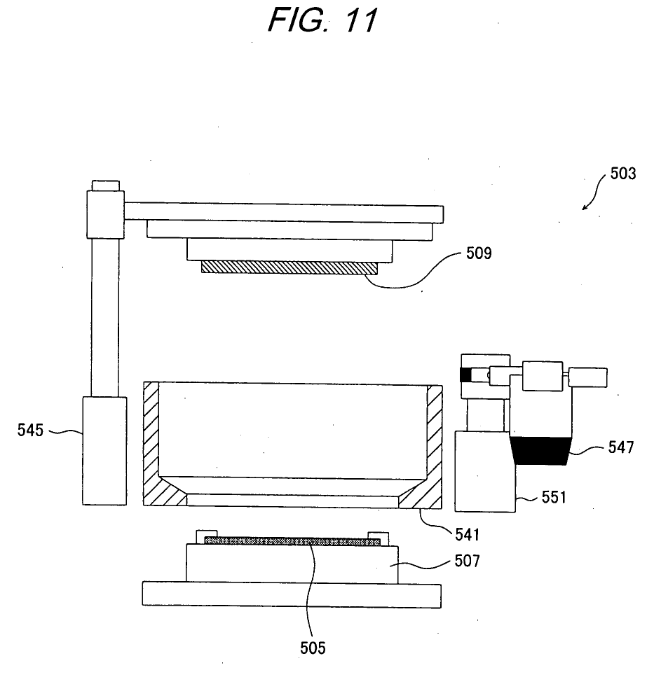

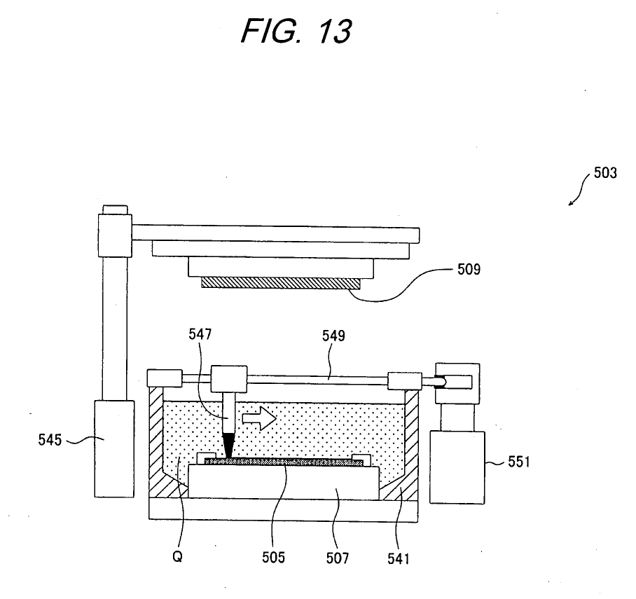

FIGS. 11 through 15 are schematic views showing the specific structure of the plating tank 503 shown in FIG. 10 and the procedure performed therein. The plating tank 503 constitutes a precipitation tank (solid particle filling mechanism) also, and comprises a substrate holder 507 for holding the substrate 505 so as to direct the surface (surface to be processed) upward and moving the substrate 505 vertically by a driving device, a plating tank body 541, disposed above the substrate holder 507, which is formed into a cylindrical body so as to surround the substrate holder 507, a counter electrode 509, disposed above the plating tank body 541, which is movable vertically by a driving device 545, and a squeegee (solid particle removing mechanism) 547 arranged near the outside of the plating tank body 541. As shown in FIG. 13, the squeegee (spatula) 547 is guided by a guide rod 549 arranged horizontally and is moved along the guide rod 549. The guide rod 549 is attached to a squeegee driving mechanism 551 so that the guide rod 549 is movable vertically and is swingable horizontally.

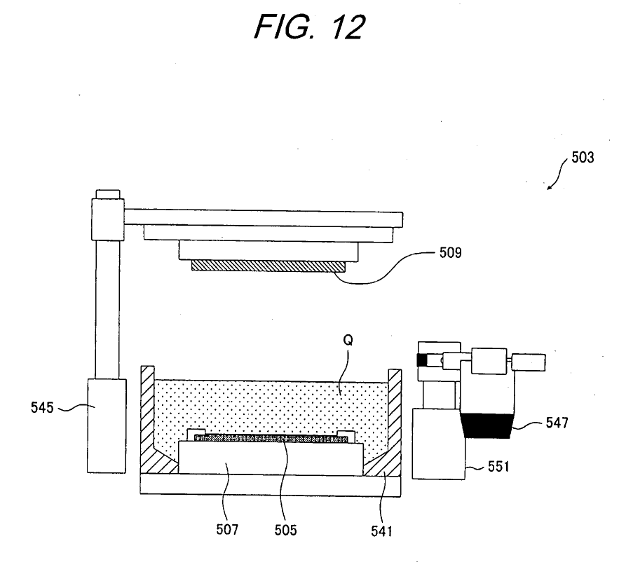

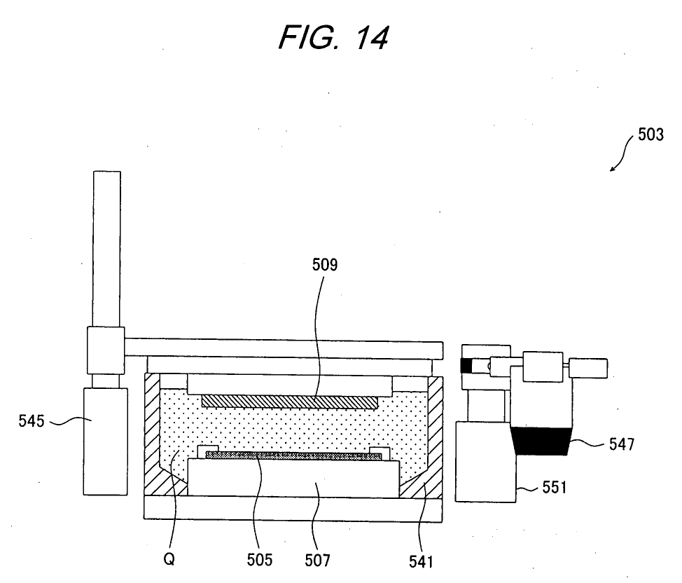

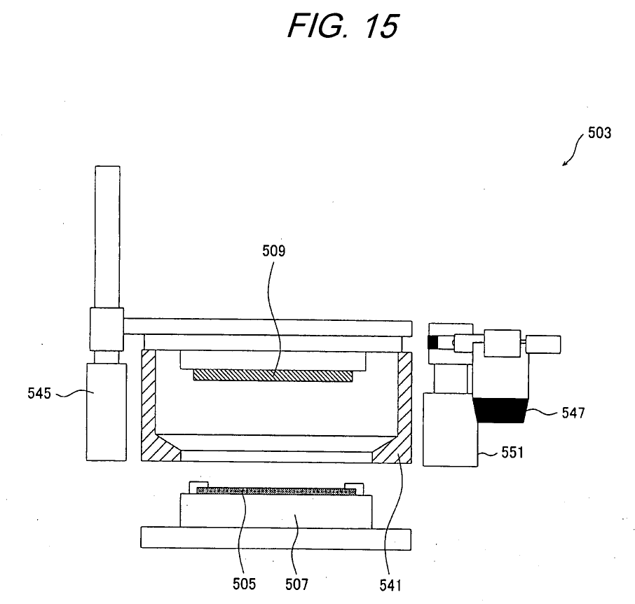

In the plating tank 503 thus constructed, as shown in FIG. 11, the substrate 505 to be processed is held by the substrate holder 507 so as to direct the surface to be processed upward. Next, as shown in FIG. 12, the substrate holder 507 is elevated and coupled to the lower side of the plating tank body 541, thus constructing a precipitation tank. As shown in FIG. 10, the plating solution Q in which the filler is dispersed is supplied to the plating tank body 541 by operating the pump 517. Then, the plating tank body 541 to which the plating solution is supplied is allowed to stand for a certain period of time. After the certain period of time, the filler is precipitated on the surface of the substrate 505, and then the squeegee 547 is inserted into the plating tank body 541 to bring the forward end of the squeegee 547 into contact with the substrate 505 as shown in FIG. 13. Then, the forward end of the squeegee 547 rubbs the surface of the substrate 505 to remove the excess filler deposited on the surface of the substrate 505, except for the surface part of non-through hole. Next, as shown in FIG. 14, the squeegee 547 is removed from the plating tank body 541 to be returned to its original position. Thereafter, the counter electrode 509 is lowered by the driving device 545 and is inserted into the plating tank body 541 to be soaked into the plating solution Q. Then, electroplating is performed under predetermined conditions. By this plating, a plated film is formed in the non-through hole and on the surface of the substrate 505 to perform filling of the non-through hole. Then, as shown in FIG. 15, the substrate holder 507 is lowered to discharge the plating solution Q from the plating tank body 541. The discharged plating solution Q is returned to the plating solution supply tank 513 as shown in FIG. 10, and is reused. On the other hand, the substrate 505 is removed from the substrate holder 507, and is then cleaned and dried, and the dried substrate 505 is supplied to the subsequent process (for example, polishing process).

In the plating tank 503 shown in FIG. 11, as a method for filling the non-through hole with the filler, a method for precipitating the filler by allowing the plating solution to stand is used. However, a method for filling the non-through hole with the filler forcibly by electrostatic adsorption (electrostatic force) or centrifugation (centrifugal force) maybe used. As an example of a solid particle filling mechanism which utilizes electrostatic adsorption, a method which uses an electrophoresis tank may be used. For example, when the filler is dispersed in a solution, cationic surfactant is used to cause the surface of the filler particle to be positively charged. Then, negative electric potential is applied to the substrate to cause the filler to be attracted to the surface of the substrate by electrostatic force. Electrostatic adsorption and precipitation by allowing the plating solution to stand may be simultaneously performed. By using these adsorption and precipitation together, precipitation rate of the filler can be increased and filling rate of the filler in the non-through hole can be increased.

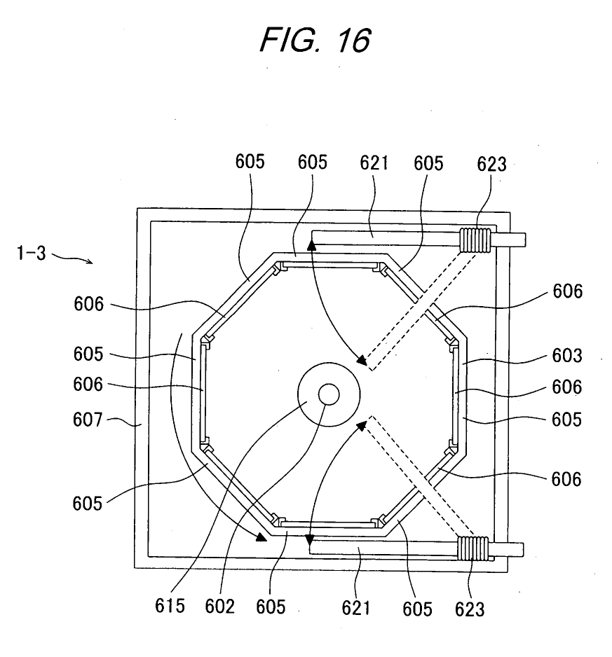

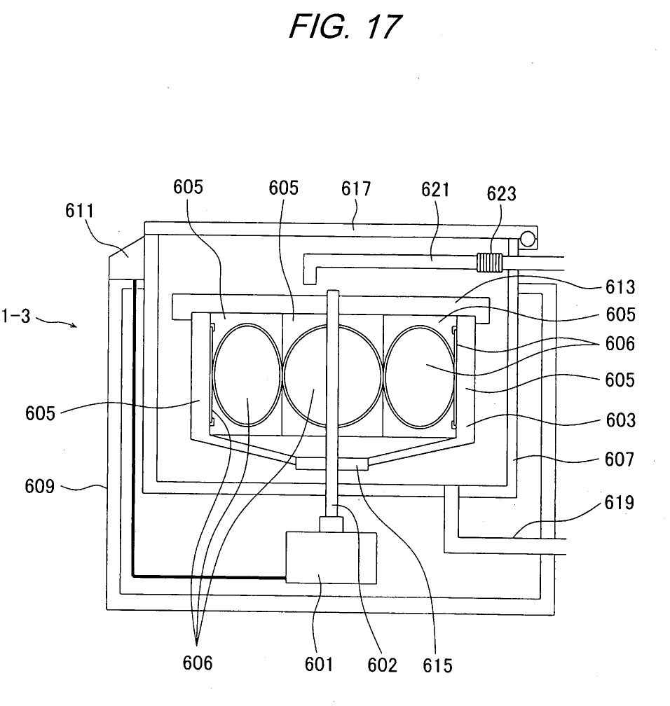

FIGS. 16 and 17 are views showing a substrate processing apparatus 1-3 having a solid particle filling mechanism for filling a non-through hole with filler by a centrifugal separating mechanism, FIG. 16 is a schematic plan view showing the substrate processing apparatus 1-3 (a casing 609, an inner lid 613 and an upper lid 617 shown in FIG. 17 are omitted), and FIG. 17 is a schematic side cross-sectional view of the substrate processing apparatus 1-3. As shown in FIGS. 16 and 17, the substrate processing apparatus 1-3 comprises a driving device (hereinafter referred to as motor) 601, a rotating tank 603 which is rotated by a rotating shaft 602 of the motor 601, a plurality of substrate holders 605 (eight in this embodiment) provided on the wall of the rotating tank 603, an outer tank 607 provided so as to surround the rotating tank 603, a casing 609 configured to enclose the outer tank 607, and a control unit 611 disposed at the upper part of the casing 609 for controlling the motor 601. The upper opening of the rotating tank 603 is covered by the inner lid 613, and a drain 615 which is freely openable and closable is provided at the central part of the rotating tank 603. The upper opening of the outer tank 607 is covered by the upper lid 617, and a discharge pipe 619 is attached to the bottom surface of the outer tank 607. Further, two introduction pipes 621 are attached to the upper part of the outer tank 607. The introduction pipes 621 are inserted into the outer tank 607, and a driving unit 623 is provided at the base portion of each of the introduction pipes 621 to swing the forward end portion of the introduction pipe 621 freely in a horizontal plane. Thus, the forward end portion of the introduction pipe 621 can be swung between the outside of the rotating tank 603 and the inside of the rotating tank 603.

The substrate 606 is fixed to each of the substrate holders 605, and the drain 615 is closed, and the inner lid 613 is opened. Then, the forward end of the introduction pipe 621 is moved to the upper part of the rotating tank 603 as shown by dotted lines in FIG. 16, and the filling liquid in which the filler is dispersed is supplied from the introduction pipe 621 to the rotating tank 603. Then, the introduction pipe 621 is retracted, and the inner lid 613 and the upper lid 617 are closed. Then, the motor 601 is operated to rotate the rotating tank 603 for a predetermined period of time, and thus the filler in the filling liquid is precipitated on the surface of the substrate 606. The precipitation rate v is expressed by the following equation (1).

$$v = \frac{{d}^{2}}{18} \cdot \frac{( σ - ρ )}{η} \cdot r {ω}^{2} \qquad ( 1 )$$

d: grain size of filler (cm), σ: density of filler (g/cm³),
p: density of solution (g/cm³),
η: viscosity of solution (g/cm·s), r: radius of rotation (cm),
ω: rotation angle speed (rad/s)

Centrifugation processing conditions are determined on the basis of the equation (1), the apparatus performance, the filler, and properties of solution. After centrifugation is performed at a certain rotational speed for a certain period of time, the drain 615 is opened to discharge the filling liquid, and the substrate 601 is removed from the rotating tank 603. The substrate 606 which has been removed from the rotating tank 603 has the filler not only in the non-through hole but also on the entire surface of the substrate 606. Thus, while the filler is left in the non-through hole, the excess filler is removed form the flat portion on the surface of the substrate 606, thus forming a conductive layer by the plating method.

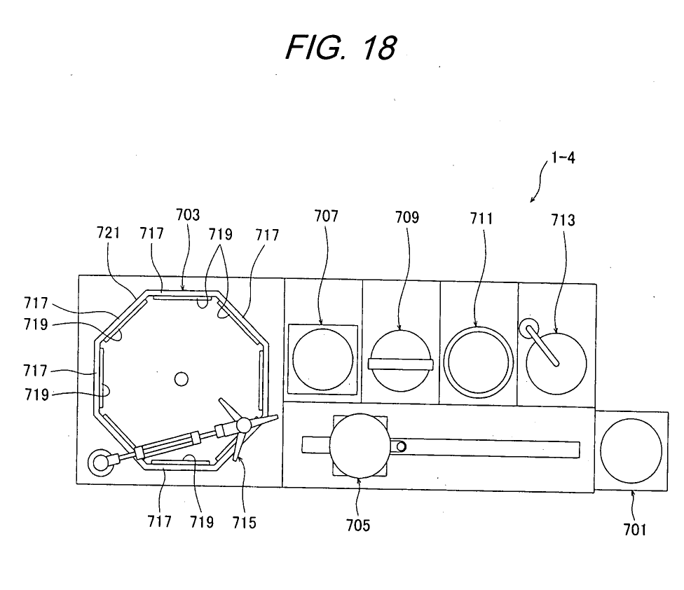

FIG. 18 is a schematic view showing a substrate processing apparatus 1-4 for performing sequential processing of filling non-through hole of a substrate with filler by centrifugation, and plating the substrate to form a conductive layer. The substrate processing apparatus 1-4 comprises a substrate case 701 for housing substrates, a solid particle filling mechanism (centrifugal mechanism) 703 having the same structure as that in the substrate processing apparatus 1-3 shown in FIGS. 16 and 17, a transfer robot 705 for transferring the substrate, a buffer tank (substrate storage mechanism) 707 for temporarily storing the substrate, which has been processed by the solid particle filling mechanism 703, in the liquid, a filler removing tank (solid particle removing mechanism) 709, a plating tank 711 for plating the substrate, and a cleaning and drying tank 713 for cleaning and drying the substrate. A transfer arm 715 is provided on the solid particle filling mechanism 703 for supplying the substrate 719 to each of the substrate holders 717 in the solid particle filling mechanism 703 or removing the substrate 719 from each of the substrate holders 717.

In the substrate processing apparatus 1-4 thus constructed, the substrate housed in the substrate case 701 is removed by the transfer robot 705 and is transferred to the solid particle filling mechanism 703 by the transfer robot 705. The transfer arm 715 receives the substrate from the transfer robot 705, and sets the substrate onto each of the substrate holders 717 in the solid particle filling mechanism 703. Thereafter, as described above, the filling liquid is introduced into the rotating tank 721 in the solid particle filling mechanism 703, and the filler is deposited on the surface of the substrate 719 by centrifugation. The substrate 719 on which the filler is deposited is removed from the solid particle filling mechanism 703 by the transfer arm 715 and is transferred to the transfer robot 705, and is then supplied to the buffer tank 707 by the transfer robot 705. The buffer tank 707 serves as a storage tank for storing the substrate to prevent the filler from being dried or being removed from the substrate until the substrate can be processed in the subsequent process, and the buffer tank 707 houses the same number of the substrates as the number of the substrates housed in the solid particle filling mechanism 703. In the buffer tank 707, the substrates are soaked in the solution such as a plating solution. Next, the substrate is transferred to the filler removing tank 709 by the transfer robot 705. In the filler removing tank 709, the surface of the substrate is rubbed by a spatula, a brush, a sponge, water flow supplied from a water flow supply device, or air flow supplied from an air flow supply device to remove excess filler while the filler filled in the non-through hole is left. Next, the substrate from which the excess filler has been removed is supplied to the plating tank 711 by the transfer robot 705, and electroplating is performed in the plating tank 711 to form a conductive layer. Thereafter, the substrate is supplied to the cleaning and drying tank 713 by the transfer robot 705, and the plating solution adhering to the surface of the substrate is removed by pure water. Then, the substrate is dried by spin drying, and is then returned to the substrate case 701 by the transfer robot 705. Thus, a series of substrate processing is completed.

In the second invention, a process of filling of the filler into the substrate and a process of plating the substrate are separately performed, but these processes may be simultaneously performed. For example, in the case of the apparatus shown in FIGS. 11 through 15, the process for removing the excess filler as shown in FIG. 13 may be omitted, and the plating process shown in FIG. 14 may be started with out waiting for participation of the filler completely. Further, in the apparatus shown in FIGS. 16 and 17, the substrate 606 held by the substrate holder 605 may serve as negative electrode, and the counter electrode serving as positive electrode may be provided on the rotating shaft 602, and plating may be performed while rotating the rotating tank 603. At this time, power may be supplied from the outside to the substrate 606 and the counter electrode using brush contacts. In addition, a power supply such as a battery charger and a power control may be placed on the rotating tank 603 and may be rotated together with the rotating tank 603. In this case, processing time per a substrate can be shortened and plating speed can be increased to certain degree. However, because a large amount of filler is entrapped in the plated film at the flat portion other than the non-through hole, burden on the removing process for removing the excess plated film is increased. Thus, it is necessary to adjust the amount of filling of the filler and the thickness of the plated film in consideration of both of the plating process and the removing process.

### EXAMPLE 1

### Example of the First Invention

A basic plating bath was prepared by adding additives to a copper plating solution, for semiconductor backend process, composed mainly of copper sulfate. Hexadecyltrimethylammonium chloride was used as cationic surfactant, and PTFE powder (Fluon PTFE manufactured by Asahi Glass Co., Ltd.) was used as filler, thus making up a plating solution. The concentration of PTFE powder was 20 g/L, and the concentration of the surfactant was determined based on the surface tension of the plating solution. A substrate having a copper film formed on a Si substrate by a sputtering method was used, and a SUS plate was used as a counter electrode. The plating was carried out using a plating solution containing the filler and using a plating solution (basic plating bath) containing no filler, respectively by a constant current method in which current value and plating time were fixed. The thicknesses of the films on the specimens after plating were measured using a scanning electron microscope (SEM) to compare the effect of increase in thickness of the film by addition of the filler.

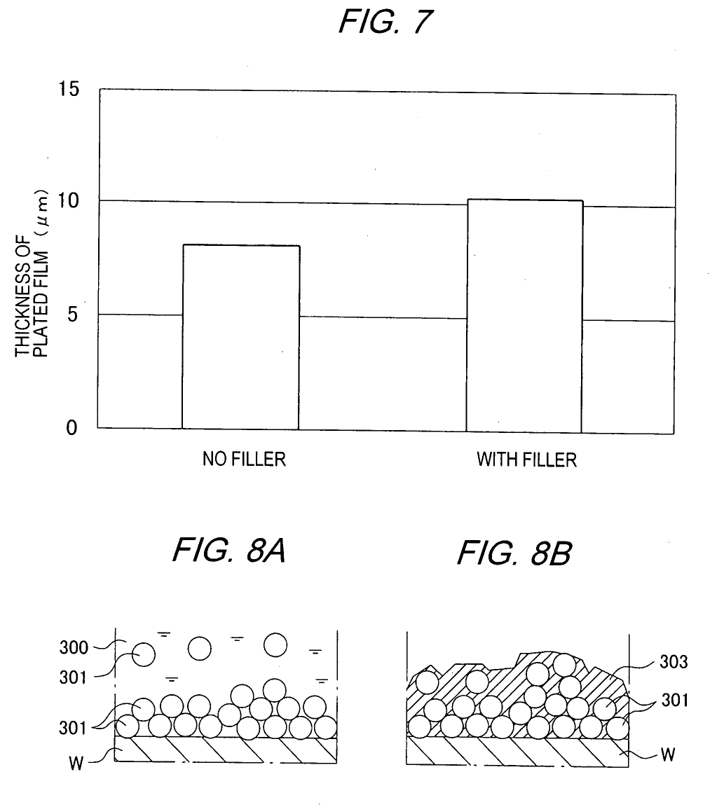

FIG. 7 shows comparison of the thicknesses of the plated films on the specimens. In the case of using PTFE filler, the effect of increase of about 27% in thickness of the plated film was observed.

### EXAMPLE 2

### Eample of the Second Invention

### (1) Example of Precipitation by Gravity of Filler

A basic plating bath was prepared by adding additives to a copper plating solution, for semiconductor backend process, composed mainly of copper sulfate. Hexadecyltrimethylammonium chloride was used as cationic surfactant, and PTFE powder (Fluon PTFE manufactured by Asahi Glass Co., Ltd. (particle diameter is equal to about 1 μm)) was used as filler, thus making up a plating solution. The concentration of PTFE powder was 20 g/L, and the concentration of the surfactant was determined based on the surface tension of the plating solution. A substrate having a copper film formed on a Si substrate by a sputtering method was used, and a SUS plate was used as a counter electrode. The plating was carried out using a plating solution containing the filler by a constant current method in which current value and plating time were fixed. The direction of the substrate was two directions of vertical and face up. The thicknesses of the films on the specimens after plating were measured using a scanning electron microscope (SEM) to compare the effect of increase in thickness of the film by addition of the filler.

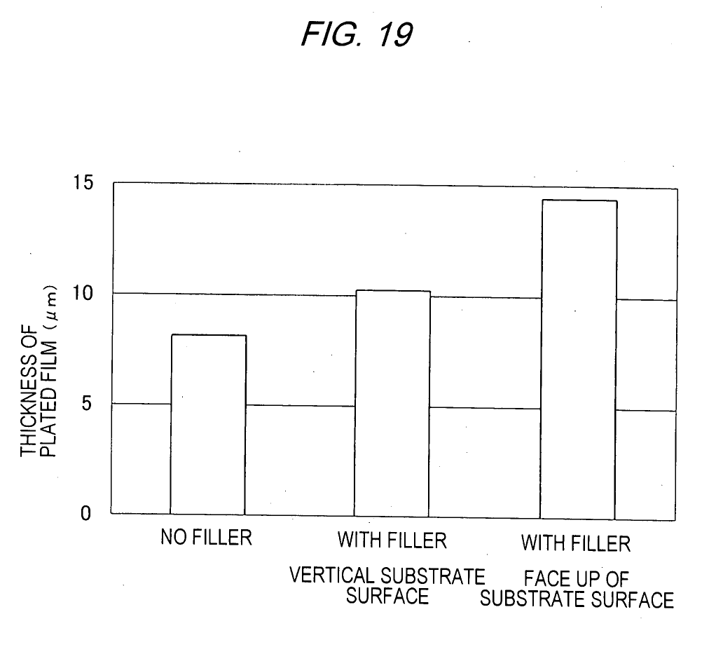

FIG. 19 shows comparison of the thicknesses of the plated films on the specimens. In the case where the surface of the substrate faced upward and the filler was precipitated, the effect of increase of about 78% in thickness of the plated film was observed. In order to remove an effect of precipitation by gravity, in the case where the surface of the substrate was vertical, the effect of increase of about 27% in thickness of the plated film was observed.

### (2) Example of Precipitation by Centrifugal Force of Filler

Al₂O₃ powder (ADMAFINE alumina by Admatechs) was prepared as filler, and a plating solution containing Al₂O₃ filler was prepared. The concentration of Al₂O₃ powder was 10 g/L, and the concentration of the surfactant was determined based on the surface tension of the plating solution. A substrate having a copper film formed by a sputtering method on a Si substrate having square non-through hole with a side of about 80 μm and a depth of about 100 μm was prepared. The substrate was set to cause the surface of the substrate to face a rotating axis of a centrifugal separator, and the plating solution containing Al₂O₃ filler was put into a rotating tank and the rotating tank was rotated at a rotational speed of 6000 rpm for five minutes to deposit the filler on the surface of the substrate. After removing the substrate from the centrifugal separator, the surface of the substrate was rubbed by a cellulose wiper to remove excess filler from the surface of the substrate. Next, a conductive layer was formed by a plating method. A copper plating solution for the semiconductor backend process was used as a plating solution, and a SUS plate was used as a counter electrode. Current value and plating conditions were adjusted suitably and copper plating was performed on the substrate.

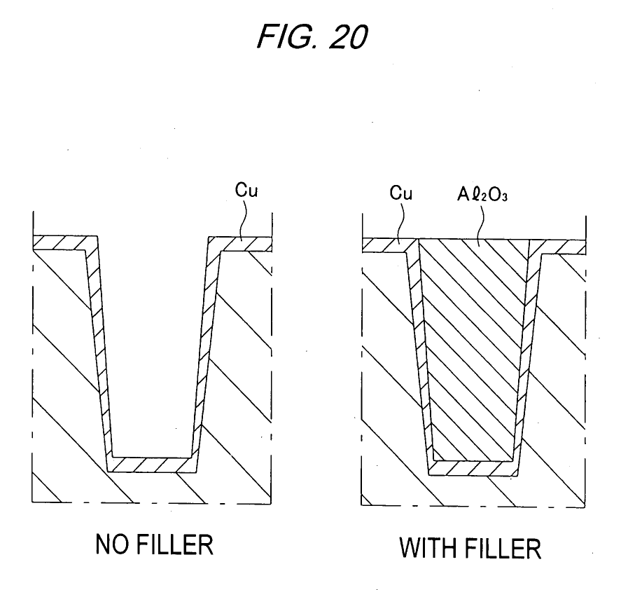

The plating time was about 20 minutes and constant. FIG. 20 is a schematic view showing cross-section structures of the specimens. It was confirmed that filling rate of the interior of the non-through hole was greatly improved in the specimen using the filler, compared with the specimen using no filler. Voids were hardly observed in the interior of the non-through hole by filling the non-through hole with the filler. Composition distribution was measured by Energy Dispersive X-ray spectroscopy (EDX). As shown in the schematic view of FIG. 20, it was confirmed that Al₂O₃ filler was observed in the interior of the non-through hole and a copper plated film grew at the side surface of the non-through hole. As a result, voids were hardly formed in the interior of the non-through hole, and an electrical connection between the surface and the backside surface of the substrate was made through the copper plated film. Thus, the non-through hole was filled with the filler, and the conductive layer having no voids was formed in a short period of time.

What is claimed is:

1. A substrate processing method comprising:
forming a non-through hole in a substrate; and
filling said non-through hole with conductive material by plating, wherein said plating uses a plating solution containing solid particles.

2. A substrate processing method according to claim 1, further comprising applying a force to said solid particles for introducing said solid particles in to said non-through hole before said plating or during said plating.

3. A substrate processing method according to claim 2, wherein said applying said force to said solid particles comprises applying said force to said solid particles in a liquid.

4. A substrate processing method according to claim 2, wherein said force comprises at least one of gravity, centrifugal force and electrostatic force.

5. A substrate processing method according to claim 1, wherein said solid particles are dispersed in said plating solution.

6. A substrate processing method according to claim 3, wherein said solid particles are dispersed in said liquid.

7. A substrate processing method according to claim 1, wherein said solid particles comprise one of metal material, ceramic material and organic material.

8. A substrate processing method according to claim 1, wherein said plating solution contains cationic surfactant.

9. A substrate processing method according to claim 3, wherein said liquid contains cationic surfactant.

10. A substrate processing apparatus comprising:
a plating apparatus for plating a substrate having a non-through hole using a plating solution to fill said non-through hole with conductive material, wherein said plating solution contains solid particles.

11. A substrate processing apparatus according to claim 10, further comprising a concentration measuring device for measuring concentration of said solid particles.

12. A substrate processing apparatus according to claim 10, further comprising a surface tension measuring device for measuring surface tension of said plating solution.

13. A substrate processing apparatus comprising:
a mechanism configured to introduce solid particles into a non-through hole of a substrate; and
a plating apparatus for plating the substrate using a plating solution to fill said non-through hole with conductive material.

14. A substrate processing apparatus according to claim 13, wherein said mechanism comprises one of a centrifugal mechanism, a precipitation tank and an electrophoresis tank.

15. A semiconductor device comprising:
a substrate;
a non-through hole formed in said substrate;
a conductor formed in said non-through hole; and
solid particles included in said conductor, wherein said solid particles comprises the same material as said conductor or different material from said conductor.
